(19) United States
(12) Patent Application Publication
(10) Pub. No.: US 2015/0287767 A1
(43) Pub. Date: Oct. 8, 2015

(54) Organic Light-Emitting Diode Display With Varying Anode Pitch

(71) Applicant: Apple Inc., Cupertino, CA (US)

(72) Inventors: Jungmin Lee, Cupertino, CA (US); ChoongHo Lee, Cupertino, CA (US); Jinkwang Kim, Cupertino, CA (US)

(21) Appl. No.: 14/498,914

(22) Filed: Sep. 26, 2014

Related U.S. Application Data
(60) Provisional application No. 61/976,987, filed on Apr. 8, 2014.

(51) Int. Cl. H01L 27/32; H01L 51/50; H01L 51/52

(52) U.S. Cl. CPC H01L 27/3216; H01L 51/5206; H01L 51/5221; H01L 27/3218; H01L 51/5056; H01L 51/5072; H01L 51/5088; H01L 51/5092

(57) ABSTRACT

An electronic device may include a display having an array of organic light-emitting diode display pixels including red, green, and blue pixels. Anodes in the pixels of each color may have a variable pitch along a first dimension on a display substrate and a constant pitch along a second dimension on the display substrate that is orthogonal to the first dimension. Anodes in a row of red pixels may have a variable pitch along the row. anodes in a row of green pixels may have a variable pitch along the row, and anodes in a row of blue pixels may have a variable pitch along the row. The anodes of each different color of pixel may have constant pitches along columns of the array.

This application claims the benefit of provisional patent application No. 61/976,987 filed Apr. 8, 2014, which is hereby incorporated by reference herein in its entirety.

### BACKGROUND

This relates generally to electronic devices and, more particularly, to electronic devices with organic light-emitting diode displays.

Electronic devices often include displays. For example, an electronic device may have an organic light-emitting diode display with an array of display pixels. The display pixels may be formed from layers of material such as anode and cathode structures and interposed materials such as organic emissive layer material.

Organic light-emitting diode structures such as the organic emissive materials and other structures in the display pixels may be deposited by thermal evaporation. A shadow mask may be used in defining the pattern of the evaporated material that is to be deposited onto a display substrate. A thermal evaporation tool may have a linear evaporation source that is scanned across the shadow mask. In the dimension parallel to the length of the linear evaporation source, there can be considerable variation in the angle of incidence of evaporated material reaching the display substrate. This may lead to undesired variations in the profiles of deposited emissive layer structures. Although profile variations can be accommodated by increasing the size of the deposited structures relative to underlying display pixel structures such as anode structures, this tends to reduce the aperture ratio of the display pixels and thereby reduce display efficiency.

It would therefore be desirable to be able to provide improved displays such as improved organic light-emitting diode displays formed by thermal evaporation.

### SUMMARY

An electronic device may include a display having an array of organic light-emitting diode display pixels including red, green, and blue pixels. Anodes may be formed in an array on a display substrate. Shadow masks with regularly spaced openings may be used to pattern emissive layer structures and other organic layers over the anodes. A linear evaporation source may be used to supply evaporated material. The evaporation source may produce evaporated material with a range of incident angles relative to its longitudinal dimension. To accommodate this angular spread, anodes may be formed with a variable pitch.

In particular, anodes in the pixels of each color may have a progressively varying pitch along a first dimension on a display substrate and a constant pitch along a second dimension on the display substrate that is orthogonal to the first dimension. For example, anodes in a row of red pixels may have a variable pitch along the row, anodes in a row of green pixels may have a variable pitch along the row, and anodes in a row of blue pixels may have a variable pitch along the row. Columns of anodes of each different color of pixel may have constant pitches.

### BRIEF DESCRIPTION OF THE DRAWINGS

FIG. 1 is a diagram of an illustrative electronic device having a display in accordance with an embodiment.

FIG. 2 is a diagram of an illustrative organic light-emitting diode display in accordance with an embodiment.

FIG. 3 is a cross-sectional side view of a portion of an illustrative organic light-emitting diode display in accordance with an embodiment.

FIG. 4 is a side view of an illustrative thermal evaporation tool being used to deposit evaporated material onto a display substrate through a shadow mask in accordance with an embodiment.

FIG. 5 is a top view of an illustrative display pixel structure in which an evaporated structure such as an evaporated emissive layer structure is being deposited over an underlying structure such as a display pixel anode in accordance with an embodiment.

FIG. 6 is a cross-sectional side view of an evaporation tool showing how evaporated material may be deposited onto a display substrate with a symmetrical profile using an opening in the center of a shadow mask in accordance with an embodiment.

FIG. 7 is a cross-sectional side view of an evaporation tool showing how evaporated material may be deposited onto a display substrate with an asymmetrical profile using an opening at the edge of the shadow mask in accordance with an embodiment.

FIG. 8 is a top view of an illustrative display substrate with variably spaced anode structures in accordance with an embodiment.

FIG. 9 is a cross-sectional side view of a display pixel structure showing how variable anode placement may result in satisfactory margins when evaporating structures on top of the anode during display fabrication operations in accordance with an embodiment.

FIG. 10 is a top view of a display substrate for a display with pixels of different colors having a variable anode pitch along rows of anodes of each color and having a constant anode pitch along columns of anodes of each color.

### DETAILED DESCRIPTION

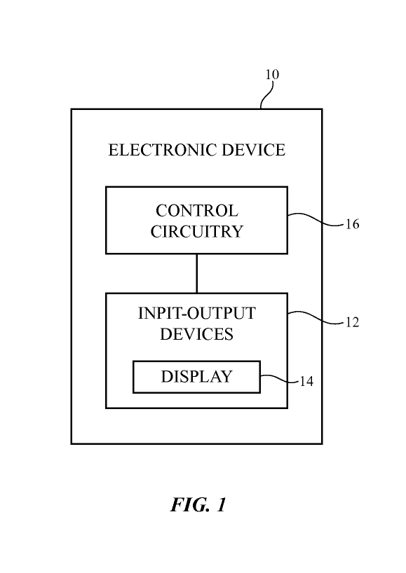

An illustrative electronic device of the type that may be provided with an organic light-emitting diode display is shown in FIG. 1. As shown in FIG. 1, electronic device 10 may have control circuitry 16. Control circuitry 16 may include storage and processing circuitry for supporting the operation of device 10. The storage and processing circuitry may include storage such as hard disk drive storage, nonvolatile memory (e.g., flash memory or other electrically-programmable-read-only memory configured to form a solid state drive), volatile memory (e.g., static or dynamic random-access-memory), etc. Processing circuitry in control circuitry 16 may be used to control the operation of device 10. The processing circuitry may be based on one or more microprocessors, microcontrollers, digital signal processors, baseband processors, power management units, audio codec chips, application specific integrated circuits, etc.

Input-output circuitry in device 10 such as input-output devices 12 may be used to allow data to be supplied to device 10 and to allow data to he provided from device 10 to external devices. Input-output devices 12 may include buttons, joysticks, click wheels, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements.

Control circuitry 16 may be used to run software on device 10 such as operating system code and applications. During operation of device 10, the software running on control circuitry 16 may display images on display 14 in input-output devices.

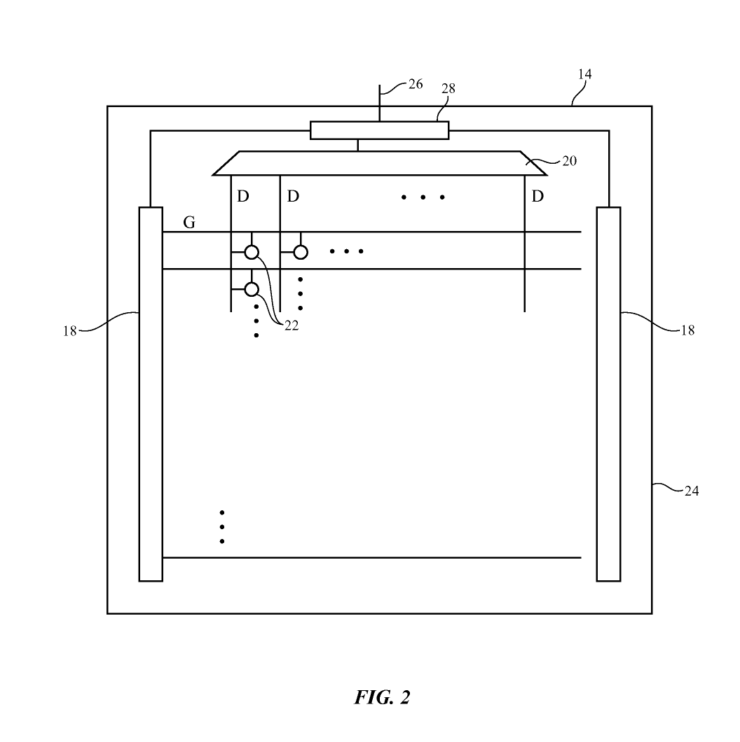

Display 14 may be an organic light-emitting diode display. As shown in the illustrative diagram of FIG. 2, display 14 may include layers such as substrate layer 24. Layers such as substrate 24 may be formed from planar rectangular layers of material such as planar glass layers, planar polymer layers, composite films that include polymer and inorganic materials, metallic foils, etc. Substrate 24 may have left and right vertical edges and upper and lower horizontal edges. If desired, substrate 24 may have non-rectangular shapes (e.g., shapes with curved edges, etc.).

Display 14 may have an array of display pixels 22 for displaying images for a user. The array of display pixels 22 may be formed from rows and columns of display pixel structures (e.g., display pixels formed from structures on display layers such as substrate 24). There may be any suitable number of rows and columns in the array of display pixels 22 (e.g., ten or more, one hundred or more, or one thousand or more).

Display driver circuitry such as display driver integrated circuit(s) 28 may be coupled to conductive paths such as metal traces on substrate 24 using solder or conductive adhesive. Display driver integrated circuit 28 (sometimes referred to as a timing controller chip) may contain communications circuitry for communicating with system control circuitry over path 26. Path 26 may be formed from traces on a flexible printed circuit or other cable. The control circuitry may be located on a main logic board in an electronic device in which display 14 is being used. During operation, the control circuitry on the logic board (e.g., control circuitry 16 of FIG. 1) may supply control circuitry such as display driver integrated circuit 28 with information on images to be displayed on display 14. Circuitry such as display driver integrated circuits may be mounted on substrate 24 or may be coupled to substrate 24 through a flexible printed circuit cable or other paths.

To display the images on display pixels 22, display driver integrated circuit 28 may supply corresponding image data to data lines D while issuing clock signals and other control signals to supporting thin-film transistor display driver circuitry such as gate driver circuitry 18 and demultiplexing circuitry 20.

Gate driver circuitry 18 (sometimes referred to as scan line driver circuitry) may be formed on substrate 24 (e.g., on the left and right edges of display 14, on only a single edge of display 14, or elsewhere in display 14). Demultiplexer circuitry 20 may be used to demultiplex data signals from display driver integrated circuit 16 onto a plurality of corresponding data lines D. With this illustrative arrangement of FIG. 1, data lines D run vertically through display 14. Data lines D are associated with respective columns of display pixels 22.

Gate lines G (sometimes referred to as scan lines) run horizontally through display 14. Each gate line G is associated with a respective row of display pixels 22. If desired, there may be multiple horizontal control lines such as gate lines G associated with each row of display pixels. Gate driver circuitry 18 may be located on the left side of display 14, on the right side of display 14, or on both the right and left sides of display 14, as shown in FIG. 2.

Gate driver circuitry 18 may assert horizontal control signals (sometimes referred to as scan signals or gate signals) on the gate lines G in display 14. For example, gate driver circuitry 18 may receive clock signals and other control signals from display driver integrated circuit 16 and may, in response to the received signals, assert a gate signal on gate lines G in sequence, starting with the gate line signal G in the first row of display pixels 22. As each gate line is asserted, data from data lines D is located into the corresponding row of display pixels. In this way, circuitry 28, 20, and 18 may provide display pixels 22 with signals that direct display pixels 22 to generate light for displaying a desired image on display 14. More complex control schemes may be used to control display pixels with multiple thin-film transistors (e.g., to implement threshold voltage compensation schemes) if desired.

Display driver circuitry such as demultiplexer circuitry 20 and gate line driver circuitry 18 may be formed from thin-film transistors on substrate 24. Thin-film transistors may also be used in forming circuitry in display pixels 22. The thin-film transistors in display 14 may, in general, be formed using any suitable type of thin-film transistor technology (e.g., silicon-based, semiconducting-oxide-based, etc.).

Display 14 may include display pixels of different colors. As an example, display 14 may include red pixels that emit red light, green pixels that emit green light, and blue pixels that emit blue light. Configurations for display 14 that include display pixels of other colors may be used, if desired. The use of a pixel arrangement with red, green, and blue pixels is merely illustrative.

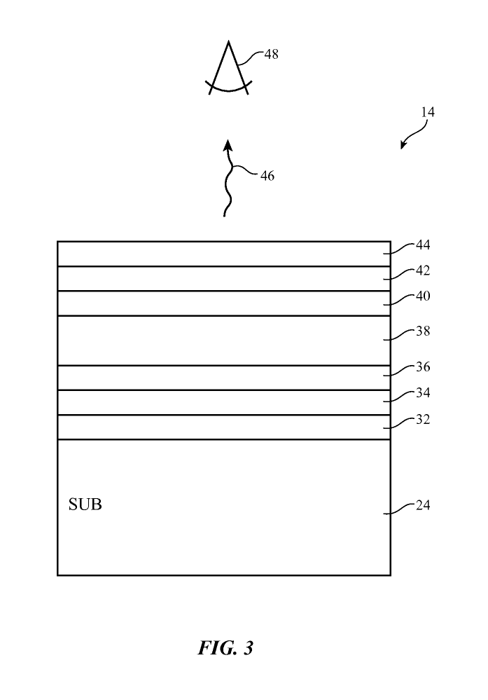

A cross-sectional side view of a configuration that may be used for the pixels of display 14 of device 10 is shown in FIG. 3. As shown in FIG. 3, display 14 may have a substrate such as substrate 24. Substrate 24 may be formed from a material such as glass or other dielectric. Anode 32 may be formed from a layer of indium tin oxide or other conductive material on the surface of substrate 30. Cathode 44 may be formed at the top of display 14. Cathode 44 may be formed from a conductive layer such as a layer of metal that is sufficiently thin to be transparent (i.e., sufficiently transparent to allow light 46 that is emitted from display 14 to travel upward towards viewer 48).

The layers of material between cathode 44 and anode 32 form a light-emitting diode. These layers may include layers such as electron injection layer 42, electron transport 40, emissive layer 38, hole transport layer 36, and hole injection layer 34. Layers 42, 40, 38, 36, and 34 may be formed from organic materials. Emissive layer 38 is an electroluminescent organic layer that emits light 46 in response to applied current.

Each display pixel 22 in display 14 may have an emissive layer 38 that emits light 46 of a different color. For example, display pixels 22 may include red pixels each having an emissive layer 38 that emits light 46 that is red, may include green pixels each having an emissive layer 38 that emits light 46 that is green, and may include blue pixels each having an emissive layer 38 that emits light that is blue. If desired, display 14 may have pixels of four colors or may have pixels of three colors plus white pixels. Color may also be imparted to pixels using a color filter layer with color filter elements that overlap the structures of FIG. 3, if desired. The configuration of FIG. 3 in which display 14 is formed from display pixels having pixels with differently colored emissive layers 38 is merely illustrative.

Emissive layer 38 (and other layers in display 14) may, if desired, be patterned by depositing these layers through a shadow mask using an evaporation tool (i.e., an evaporator). For example, red pixels formed from portions of emissive layer 38 may be formed on a display by evaporating a red emissive material with an evaporation tool while an appropriate red shadow mask is aligned with display substrate 24. The red shadow mask has an array of red pixel openings that allow red emissive material 38 to be deposited in a desired pattern on display substrate 24. Blue and green pixels may be deposited in the same way, using a blue pixel shadow mask and green pixel shadow mask, respectively.

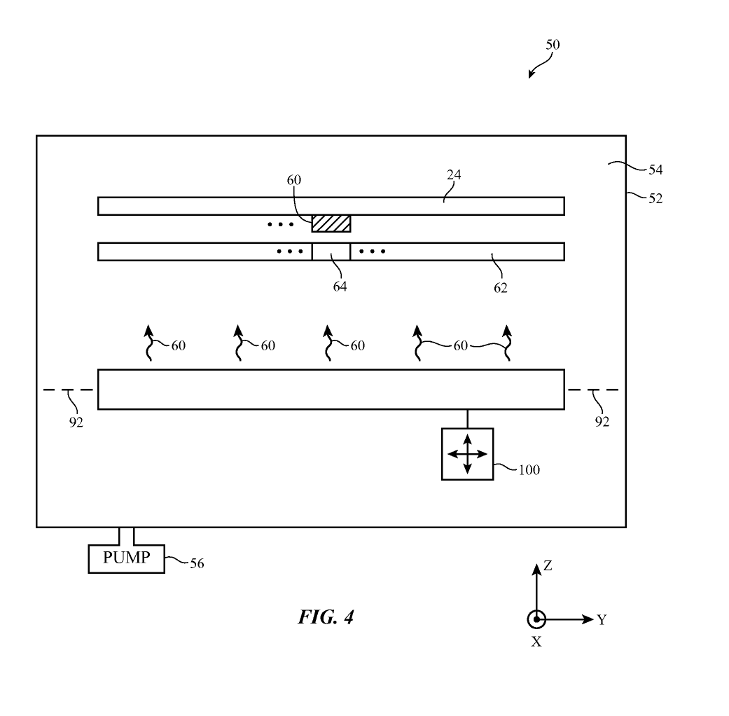

A cross-sectional side view of an evaporation tool of the type that may be used to pattern emissive layer material for red, green, and blue pixels or that may be used to deposit other materials is shown in FIG. 4. As shown in FIG. 4, evaporation tool 50 has a vacuum chamber such as chamber 52. During evaporation operations, interior 54 of chamber 52 may be evacuated of air using pump 56 (i.e., a vacuum may be created in chamber 52).

Evaporation source 58 may be a linear source that is elongated along longitudinal axis 92. With this type of configuration, source 58 is thin in lateral dimension X (i.e., into the page in the orientation of FIG. 4) and is elongated along lateral dimension Y (i.e., across the page in the orientation of FIG. 4). Source 58 may have a rectangular footprint and may have a pair of opposing elongated edges that run along dimension Y and a pair of opposing shorter edges that run along dimension X.

Evaporation source 58 has heating elements that heat materials to be evaporated. Source 58 may have orifices that serve as point sources for emitting evaporated material. Evaporated material 60 from source 58 passes through openings 64 in shadow mask 62. The portions of material 60 that pass through openings 64 form deposited structures (layers) 60 on substrate 24. Openings 64 in shadow mask 62 may, for example, be arranged in a pattern appropriate for forming an emissive layer 38 for red display pixels 22, for green display pixels 22, or for blue display pixels 22. Different masks may be used in tool 50 at different times to form emissive layer patterns for display pixels 22 of different colors or to deposit other structures for display 14.

Mask 62 may have a rectangular shape. The lateral dimension of linear source 58 along longitudinal axis 92 may be sufficient to cover the entire width of mask 62 and display substrate 24, as shown in FIG. 4. Display substrate 24 may have a size and shape corresponding to a single display 14 or may be a motherglass panel that has a size and shape sufficient to accommodate multiple displays 14. In a motherglass arrangement, the motherglass can be singulated into sections to form individual displays 14 following evaporation operations.

Although the lateral dimension of source 58 along axis 92 is sufficient to cover the width of the display substrate, linear source 58 may be too narrow in dimension X to cover all of mask 62 at once. Accordingly, linear source 58 may be scanned across mask 62 during evaporation operations using a positioner such as computer-controlled positioner 100 (i.e., source 58 may be moved in a direction that is into the page in the orientation of FIG. 4).

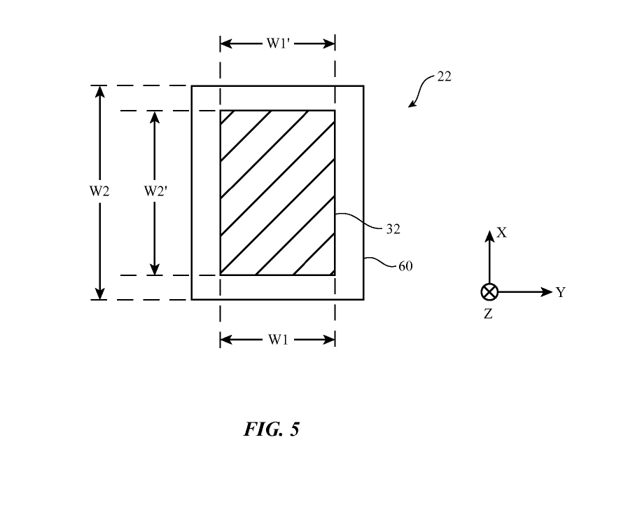

When forming display pixels 22, layers of organic material 60 such as organic emissive layer 38 (and, if desired, other layers such as organic layers 34, 36, 40, and/or 32 of FIG. 3) may be evaporated onto substrate 24 through openings 64 in shadow mask 62. The evaporated structures that are formed by evaporating material 60 through openings 64 and the other structures in display pixels 22 may be rectangular or may have other suitable shapes (i.e., other suitable footprints when viewed from above). As shown in the illustrative top view of FIG. 5, each display pixel 22 may have one or more layers of evaporated material 60 (e.g., emission layer 38 and/or other organic layers) that have been evaporated on top of structures such as display pixel anode 32.

To ensure that pixels 22 operate satisfactorily, it may be desirable for the size of evaporated structure 60 to be larger than that of anode 32, so that evaporated structure 60 will overlap all of the area of anode 32. As shown in the example of FIG. 5, satisfactory overlap of structure 60 and anode 32 may be ensured by forming structure 60 with lateral dimensions W1 and W2 that are larger than respective lateral dimensions W1′ and W2° of anode 32. To maximize display efficiency, it may be desirable to maximize dimensions W1′ and W2′ relative to dimensions W1 and W2. At the same time, anode 32 cannot be made too large relative to structure 60 or there will be an elevated risk that structure 60 will not properly overlap anode 32 due to manufacturing variations.

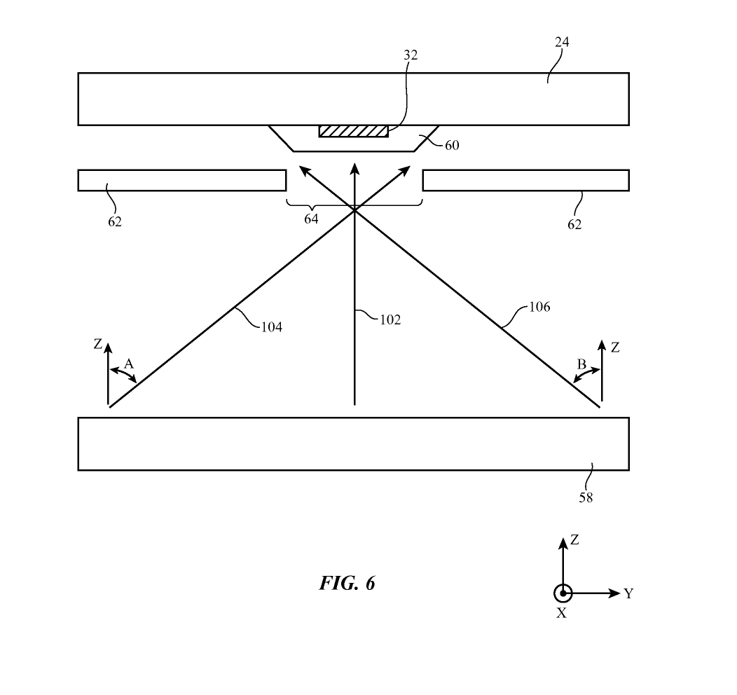

Due to the elongated nature of evaporation source 58 along axis 92, evaporated material 60 can follow trajectories with different angles to substrate 24. Consider, as an example, the situation of FIG. 6 in which opening 64 is one of the openings formed in the middle of shadow mask 62. In this type of situation, some evaporated material 60 follows a direct trajectory to substrate 24 through opening 64 (see, e.g., trajectory 102, which is parallel to vertical dimension Z). Other evaporated material (e.g., material 60 from the opposing ends of source 58) may follow more angled trajectories. For example, evaporated material from the left side of source 58 may follow angled trajectory 104, which lies at an angle A with respective to vertical dimension Z and evaporated material from the right side of source 58 may follow angled trajectory 106, which lies at an angle B with respect to vertical dimension Z. This causes material 60 to be deposited in a symmetrical trapezoidal cross-sectional shape over anode 32 (and any previously deposited organic layers).

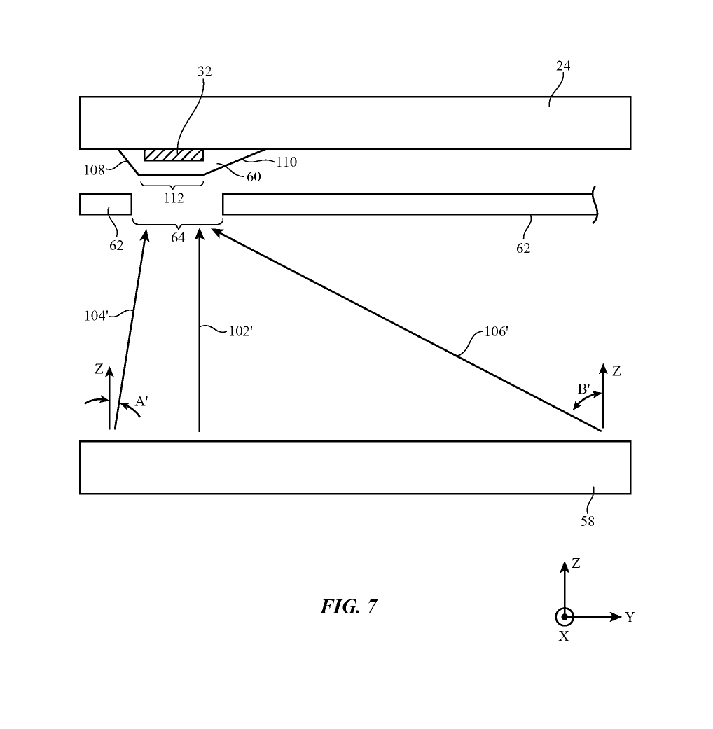

If, on the other hand, opening 64 is one of the shadow mask openings that are located near the edge of mask 62, deposited material 60 will have an asymmetric trapezoidal cross-sectional shape. This is illustrated in FIG. 7. As shown in FIG. 7, when opening 64 is near the edge of shadow mask 62 and display substrate 24, trajectory 102′ may be oriented vertically as with trajectory 102 of FIG. 6, but trajectory 106′ from the right-hand end of evaporation source 58 will be more angled with respect to vertical dimension Z than trajectory 106 of FIG. 6 and trajectory 104′ from the left-hand end of evaporation source 58 will be less angled with respect to vertical dimension Z than trajectory 104 of FIG. 6 (i.e., angle B′ will be more than angle B and angle A′ will be less than angle A). Because angles A′ and B′ are not equal, structure 60 will have an asymmetric trapezoidal cross-sectional shape (i.e., edge 108 of structure 60 will be steeper and more abrupt than edge 110 of structure 60, which will be tapered). Unless care is taken, tapered edge 110 of structure 60 will overlap the edge of anode 32 and central planar region 112 of structure 60 will not be properly centered over anode 32, leading to potential alignment issues.

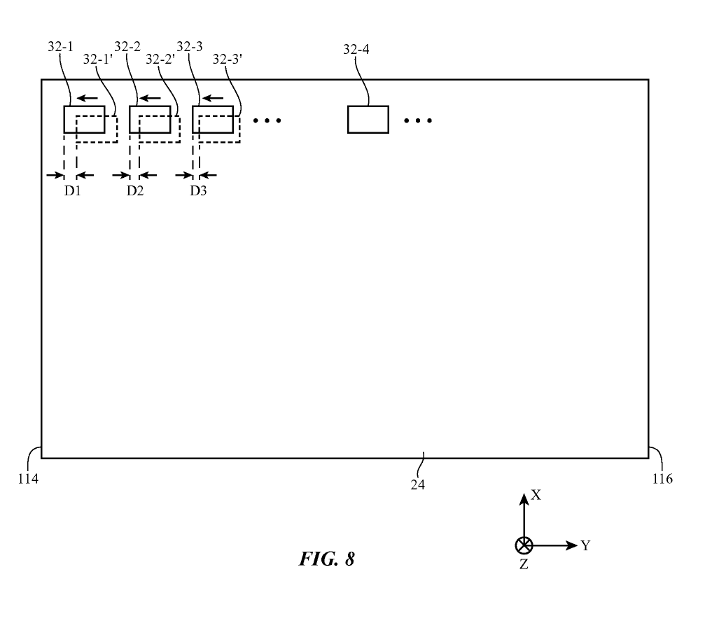

As shown in FIG. 8, proper alignment of structures evaporated through a shadow mask with evenly spaced openings 64 may be accomplished by spacing anodes 32 on display substrate 24 with a variable spacing (e.g., a progressively varying pitch) along lateral dimension Y (i.e., along the dimension parallel to longitudinal axis 92 of elongated evaporation source 58). Consider, as an example, anodes 32-1, 32-2, 32-3, and 32-4.

Anode 32-4 is located in the center of display substrate 24 (i.e., anode 32-4 is located halfway between left substrate edge 114 and right substrate edge 116). Because anode 32-4 is located at the center of display substrate 24, the position of anode 32-4 need not be modified from its nominal position. During evaporation operations, anodes such as anode 32-4 will be covered with symmetrical structures 60 of the type shown in FIG. 6.

Anodes near the edge of display substrate 24 may be shifted outwardly to ensure that the evaporated structures that are deposited on these anodes will be properly aligned with the anodes. For example, the leftmost anode in FIG. 8 may be moved from nominal position 32-1′ (i.e., a position in a regularly spaced array of anodes) to new position 32-1, the second anode to the right may be moved from nominal position 32-2′ to new position 32-2, and the third anode to the right may be moved from nominal position 32-3′ to new position 32-3.

The amount by which each anode is shifted outwardly towards edge 114 depends on the distance of that anode from edge 114. For example, shift D1 of anode 32-1 may be more than shift D2 of anode 32-2, which may in turn be more than shift D3 of anode 32-3. This variable anode spacing (anode pitch) may change in magnitude across the entire display substrate (i.e., an individual display substrate or a display substrate motherglass). On the left-hand side of the substrate being processed, the anode spacing progressively decreases as distance from the left-hand edge 114 to the center of the substrate is increased. Similarly, on the right-hand side of the substrate being processed, the anode spacing progressively decreases as distance from the right-hand edge 116 to the center of the substrate is increased.

Anode layout (i.e., the positions of the anodes on the display substrate) is determined during the metal deposition and patterning operations used during anode formation. For example, a photolithographic mask and photolithographic patterning techniques can be used to pattern the anodes or anodes can be patterned by using a shadow mask during anode deposition. Other techniques for patterning anodes 32 (e.g., inkjet printing, screen printing, etc.) may also be used, if desired.

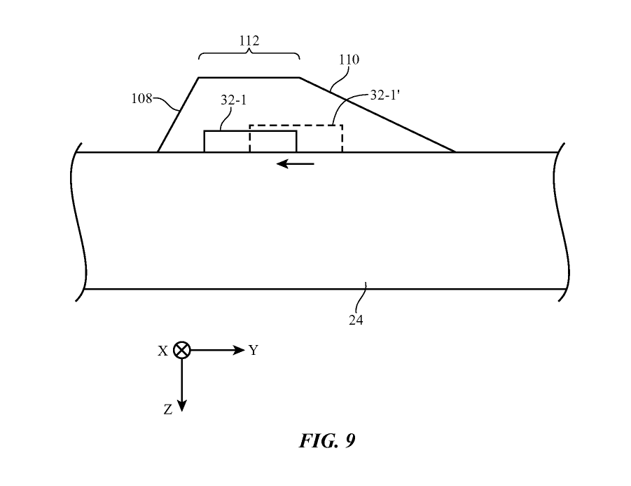

FIG. 9 is a cross-sectional side view of an illustrative display pixel structure of the type that may be formed in a display with variable anode spacing. The pixel structure of FIG. 9 includes an anode such as node 32-1 of FIG. 8 that is located near edge 114 of substrate 24 (e.g., near a motherglass edge and/or near the edge of the substrate in display 14). As a result, anode 32-1 is shifted outwardly (away from the center of substrate 24) from unmodified (fixed-anode-spacing) location 32-1′ to variable-anode-spacing location 32-1. This ensures that anode 32-1 is centered entirely under central planar portion 112 of structure 60, rather than being formed completely or partly under tapered edge portion 110 of structure 60. More than one layer of organic material may be evaporated onto anode 32-1 during fabrication of the display. For example, an emissive layer structure and/or other organic light-emitting diode layers (e.g., a carrier injection structure such as a hole injection layer, a carrier transport structure such as an electron transport layer, etc.) may be deposited.

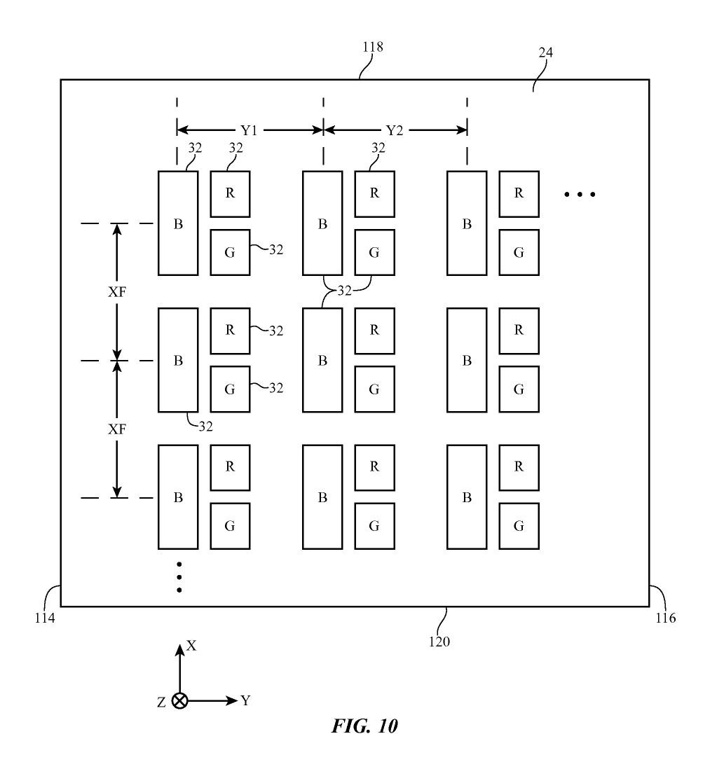

FIG. 10 is a top view of an illustrative display substrate having rows and columns of anodes 32 for red pixels (R), green pixels (G), and blue pixels B. The pitch for the blue-pixel anodes is variable in the Y dimension, parallel to upper and lower display substrate edges 118 and 120. For example, the spacing between the first and second blue-pixel anodes B in the first row of anodes in FIG. 10 (Y1) is greater than the spacing between the second and third blue-pixel anodes B in the first row of anodes in FIG. 10 (Y2). The spacing between additional blue-pixel anodes likewise varies (i.e., the anode pitch decreases across the surface of substrate 24 as a functional of increasing Y). The pitch of the blue pixel anodes on substrate 24 therefore varies as a function of distance across substrate 24, as does the pitch of the red pixel anodes on substrate 24 and the green pixel anodes on substrate 24. Anode pitch may be constant in the vertical dimension (see, e.g., constant anode-to-anode spacing XF between the anodes for each different display pixel color in the example of FIG. 10).

In some scenarios (i.e., situations in which substrate 24 is associated with a single display, anode pitch may decrease from a maximum at the left edge of the display to a minimum near the center of the display and then increase back to the maximum near the right edge of the display.

In other scenarios (i.e., situations in which substrate 24 is a motherglass panel), anode pitch may decrease toward the center of the motherglass before rising towards the right of the motherglass. When multiple displays are singulated from this motherglass, some of the displays (i.e., displays singulated from left-hand portions of the motherglass) will have progressively decreasing anode pitch along their rows of anodes, whereas other displays (e.g., displays singulated from a position near the right edge of the motherglass) will have progressively increasing anode pitch along their rows of anodes. Still other displays singulated from the center of the motherglass (e.g., a display that overlaps the center of the motherglass) may have anode pitches that decrease towards the center before rising towards the right edge.

In each of these configurations, it may be desirable to maintain a fixed anode pitch in vertical dimension X (i.e., the anode pitch may be constant in the row of blue-pixel anodes, in the row of red-pixel anodes, and in the row of green-pixel anodes, as evidenced by fixed vertical anode pitch XF parallel to edges 114 and 116 of FIG. 10). In general, the pixels of a given color in each display 14 will have a progressively varying anode pitch (anode-to-anode spacing) as a function of distance across the array in a first dimension (i.e., as a function of distance along a row of pixels of a given color in the array), and will have a constant anode pitch (anode-to-anode spacing) as a function of distance across the array in the second dimension that is orthogonal to the first dimension (i.e., as a function of distance along a column of pixels of the given color in the array). Pixel pitch for each color of pixel on substrate 24 and in display 14 may be constant in both vertical (X) and horizontal (Y) dimensions.

The foregoing is merely illustrative and various modifications can be made by those skilled in the art without departing from the scope and spirit of the described embodiments. The foregoing embodiments may be implemented individually or in any combination.

What is claimed is:

1. An organic light-emitting diode display, comprising:
a display substrate; and
an array of display pixels on the display substrate, wherein the array of display pixels comprises pixels of a given color that have a constant pixel pitch and have an array of variably spaced anodes with an anode-to-anode spacing that varies as a function of distance across the display substrate.

2. The organic light-emitting diode display defined in claim 1 further comprising an organic emissive material overlapping the anodes.

3. The organic light-emitting diode display defined in claim 2 wherein the organic emissive material comprises evaporated material that is evaporated in a pattern that overlaps the anodes by using a shadow mask with equally spaced openings.

4. The organic light-emitting diode display defined in claim 1 wherein the display pixels include evaporated structures that are evaporated in a pattern that overlaps the anodes using a shadow mask with equally spaced openings.

5. the organic light-emitting diode display defined in claim 4 wherein the evaporated structures include carrier transport structures.

6. The organic light-emitting diode display defined in claim 4 wherein the evaporated structures include carrier injection structures.

7. The organic light-emitting diode display defined in claim 1 wherein each anode has a rectangular shape.

8. The organic light-emitting diode display defined in claim 7, wherein the display substrate has edges that run parallel to first and second orthogonal dimensions, wherein the variably spaced anodes are arranged in an array having rows running parallel to the first dimension and columns running parallel to the second dimension, and wherein the anodes in the array have a variable anode-to-anode spacing in the first dimension.

9. The organic light-emitting diode display defined in claim 8 wherein the anodes have a constant anode-to-anode spacing in the second dimension.

10. The organic light-emitting diode display defined in claim 9 wherein at least some of the anodes in the array have an anode-to-anode spacing in the first dimension that decreases as a function of distance across the display substrate in the first dimension.

11. An organic light-emitting diode display, comprising:
a substrate;
an array of anodes on the substrate having a pitch that varies as a function of distance across the substrate; and
an array of organic light-emitting diodes of a given color, wherein each of the anodes forms part of a respective one of the organic light-emitting diodes.

12. The organic light-emitting diode display defined in claim 11 wherein each organic light-emitting diode includes a cathode and organic structures between the anode of that organic-light-emitting diode and the cathode.

13. The organic light-emitting diode display defined in claim 12 wherein the organic structures include an emissive layer structure in each organic light-emitting diode that overlaps the anode of that organic light-emitting diode.

14. The organic light-emitting diode display defined in claim 13 wherein the organic light-emitting diodes are red organic light-emitting diodes and wherein the emissive layer structure in each of the red organic light-emitting diodes emits red light.

15. The organic light-emitting diode display defined in claim 14 wherein the display substrate has edges that run parallel to first and second orthogonal dimensions, wherein the anodes are arranged in an array having rows running parallel to the first dimension and columns running parallel to the second dimension, and wherein the anodes in the red organic light-emitting diodes have a variable pitch along the first dimension.

16. The organic light-emitting diode display defined in claim 15 wherein anodes in the red organic light-emitting diodes have a constant pitch in the second dimension.

17. An organic light-emitting diode display, comprising:
a display substrate; and
light-emitting diodes of different colors on the substrate, each light-emitting diode including a cathode, an anode, and organic material between the cathode and anode, wherein the anodes of the light-emitting diodes are organized in rows and columns and wherein the anodes of the light-emitting diodes of each color have a variable pitch along the rows.

18. The organic light-emitting diode display defined in claim 17 wherein the light-emitting diodes comprise rows of red light-emitting diodes and wherein the anodes of the red light-emitting diodes have a progressively varying pitch along the rows.

19. The organic light-emitting diode display defined in claim 18 wherein the light-emitting diodes comprise rows of blue light-emitting diodes, wherein the anodes of the blue light-emitting diodes have a progressively varying pitch along the rows, wherein the light-emitting diodes comprise rows of green light-emitting diodes, and wherein the anodes of the green light-emitting diodes have a progressively varying pitch along the rows.

20. The array of light-emitting diodes defined in claim 19 wherein the anodes in each column of red light-emitting diodes have a fixed pitch, wherein the anodes in each column of green light-emitting diodes have a fixed pitch, and wherein the anodes in each column of blue light-emitting diodes have a fixed pitch.
